(19) United States
(12) Patent Application Publication
(10) Pub. No.: US 2026/0015720 A1
(43) Pub. Date: Jan. 15, 2026

(54) Substrate Processing Apparatus, Substrate Processing Method, Method of Manufacturing Semiconductor Device and Non-transitory Computer-readable Recording Medium

(71) Applicant: Kokusai Electric Corporation, Tokyo (JP)

(72) Inventor: Yusaku OKAJIMA, Toyama (JP)

(21) Appl. No.: 19/336,769

(22) Filed: Sep. 23, 2025

Related U.S. Application Data
(63) Continuation of application No. PCT/JP2023/011924, filed on Mar. 24, 2023.

(51) Int. Cl. C23C 16/455; C23C 16/44; C23C 16/52; H01L 21/02

(52) U.S. Cl. CPC C23C 16/45544; C23C 16/4408; C23C 16/4412; C23C 16/52; H01L 21/0217

(57) ABSTRACT

There is provided a technique that includes: a process chamber in which a substrate is processed; a first gas supplier configured to supply a first gas to a first region in the process chamber; a second gas supplier configured to supply a second gas to a second region in the process chamber different from the first region; and a controller configured to be capable of controlling the first gas supplier and the second gas supplier to supply the first gas and the second gas such that a pressure difference between the first region and the second region is reduced when the first gas is supplied in a flash-like manner.

### CROSS REFERENCE TO RELATED APPLICATIONS

This application is a bypass continuation application of PCT International Application No. PCT/JP2023/011924, filed on Mar. 24, 2023, in the WIPO, the entire contents of which are hereby incorporated by reference.

### TECHNICAL FIELD

The present disclosure relates to a substrate processing apparatus, a substrate processing method, a method of manufacturing a semiconductor device and a non-transitory computer-readable recording medium.

### BACKGROUND

According to some related arts, as a configuration of a substrate processing apparatus used in a manufacturing process of a semiconductor device, for example, a configuration in which a plurality of substrates are processed collectively while the plurality of substrates are accommodated in a substrate retainer and in which a heat transfer in an up-down direction (vertical direction) is reduced by a heat insulating assembly arranged below the substrate retainer may be used.

### SUMMARY

According to the present disclosure, there is provided a technique capable of processing a plurality of substrates uniformly.

According to an embodiment of the present disclosure, there is provided a technique that includes: a process chamber in which a substrate is processed; a first gas supplier configured to supply a first gas to a first region in the process chamber; a second gas supplier configured to supply a second gas to a second region in the process chamber different from the first region; and a controller configured to be capable of controlling the first gas supplier and the second gas supplier to supply the first gas and the second gas such that a pressure difference between the first region and the second region is reduced when the first gas is supplied in a flash-like manner.

### BRIEF DESCRIPTION OF THE DRAWINGS

FIG. 1 is a diagram schematically illustrating an exemplary configuration of a substrate processing apparatus according to one or more embodiments of the present disclosure.

FIG. 2A is a diagram schematically illustrating an example of a first process gas supply system according to the embodiments of the present disclosure, FIG. 2B is a diagram schematically illustrating an example of a second process gas supply system according to the embodiments of the present disclosure and FIG. 2C is a diagram schematically illustrating an example of an inert gas supply system according to the embodiments of the present disclosure.

FIG. 3 is a diagram schematically illustrating an example of a process gas supply system according to the embodiments of the present disclosure

FIG. 4 is a block diagram schematically illustrating an example of a functional configuration of a controller and related components of the substrate processing apparatus according to the embodiments of the present disclosure.

FIG. 5 is a flow chart schematically illustrating a substrate processing flow according to the embodiments of the present disclosure.

FIG. 6 is a diagram schematically illustrating a specific example of a control process when a gas supply is performed according to the embodiments of the present disclosure.

FIG. 7 is a diagram schematically illustrating another specific example of the control process when the gas supply is performed according to the embodiments of the present disclosure.

FIG. 8 is a diagram schematically illustrating still another specific example of the control process when the gas supply is performed according to the embodiments of the present disclosure.

FIG. 9 is a diagram schematically illustrating still another specific example of the control process when the gas supply is performed according to the embodiments of the present disclosure.

### DETAILED DESCRIPTION

Hereinafter, one or more embodiments (also simply referred to as “embodiments”) of the technique of the present disclosure will be described in detail with reference to the drawings. The drawings used in the following descriptions are all schematic. For example, a relationship between dimensions of each component and a ratio of each component shown in the drawing may not always match the actual ones. In addition, even between the drawings, the relationship between the dimensions of each component and the ratio of each component may not always match.

### (1) Configuration of Substrate Processing Apparatus

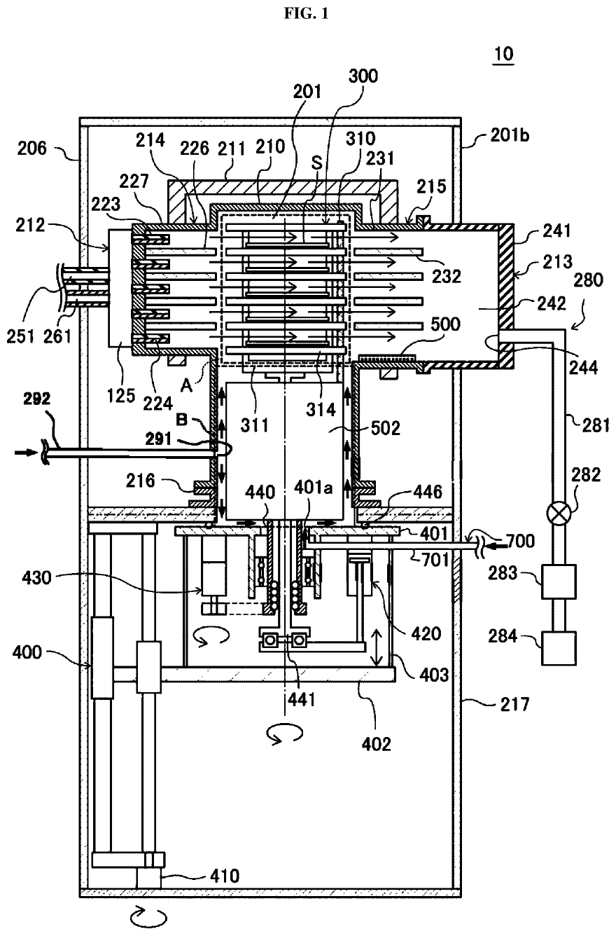

A configuration of a substrate processing apparatus 10 according to the present embodiments will be described with reference to FIG. 1.

### <Overall Configuration>

The substrate processing apparatus 10 is roughly divided into a reaction tube storage chamber 206 and a transfer chamber 217. The reaction tube storage chamber 206 is provided above the transfer chamber 217.

### <Reaction Tube Storage Chamber>

The reaction tube storage chamber 206 may include: a reaction tube 210 of a cylindrical shape extending in a vertical direction; a heater 211 serving as a heating structure (furnace structure) installed on an outer periphery of the reaction tube 210; a process gas supply structure 212 serving as a part of a first gas supplier; and a gas exhaust structure 213 serving as a part of an exhauster. According to the present embodiments, the reaction tube 210 may also be referred to as a “process chamber”, and an inner space of the reaction tube 210 may also be referred to as a “processing space”.

The reaction tube 210 is configured to be capable of storing (or accommodating) a substrate retainer (which is a substrate support or a substrate holder) 300 described later. That is, the substrate retainer 300 configured to support (or hold) a plurality of substrates S can be transferred (loaded) into a process chamber 201 configured by the reaction tube 210. Hereinafter, each of the plurality of substrates S may also be referred to as a “substrate S”. Then, the substrate S is processed in the process chamber 201. Therefore, the process gas supply structure 212, an inside (inner portion) of the reaction tube 210 and the gas exhaust structure 213 are horizontally in communication with one another in a horizontal direction.

The process gas supply structure 212 is provided upstream in a gas flow direction at a side of the reaction tube 210. A gas such as a process gas is supplied into the process chamber 201 in the reaction tube 210 through the process gas supply structure 212. Then, the gas is supplied to the substrate S in the horizontal direction. The gas exhaust structure 213 is provided downstream in the gas flow direction at another side of the reaction tube 210, and the gas in the reaction tube 210 is discharged (exhausted) through the gas exhaust structure 213. The gas exhaust structure 213 is disposed opposite to the process gas supply structure 212 with the reaction tube 210 interposed therebetween.

On an upstream side of the reaction tube 210 between the reaction tube 210 and the process gas supply structure 212, an upstream side gas guide 214 configured to adjust a flow of the gas supplied through the process gas supply structure 212 is provided. In addition, on a downstream side of the reaction tube 210 between the reaction tube 210 and the gas exhaust structure 213, a downstream side gas guide 215 configured to adjust the flow of the gas discharged from the reaction tube 210 is provided. A lower end of the reaction tube 210 is supported by a manifold 216.

That is, in the reaction tube storage chamber 206, the reaction tube 210, the upstream side gas guide 214 and the downstream side gas guide 215 are provided. The first gas supplier may further include the upstream side gas guide 214, a plurality of nozzles 223, or a plurality of nozzles 224 described later. Hereafter, each of the nozzles 223 may also be simply referred to as a “nozzle 223”, and each of the nozzles 224 may also be simply referred to as a “nozzle 224”. In addition, the exhauster may further include the downstream side gas guide 215.

The reaction tube 210, the upstream side gas guide 214 and the downstream side gas guide 215 are implemented as a continuous structure. For example, each of the reaction tube 210, the upstream side gas guide 214 and the downstream side gas guide 215 is made of a material such as quartz and silicon carbide (SiC). In addition, each of the reaction tube 210, the upstream side gas guide 214 and the downstream side gas guide 215 is constituted by a heat transmittable structure capable of transmitting a heat radiated from the heater 211. The heat of the heater 211 can heat the substrate S or the gas. As the heater 211, for example, a resistance type heater capable of being turned on/off and capable of controlling a heating temperature may be used. In addition, the heater 211 is provided (disposed) on a side of the process chamber 201 such that the heater 211 is configured to be capable of heating the process chamber 201.

The process chamber 201 configured by the reaction tube 210 may include: a processing region (which is a processing area) A in which the substrate S is processed; and a heat insulating region (which is a heat insulating area) B provided below the processing region A. In the heat insulating region B, a heat insulator 502 serving as a heat insulating structure described later is disposed while the substrate retainer 300 is transferred (loaded) into the process chamber 201. The heat insulator 502 may also be referred to as a “heat insulating assembly”.

In a manner described above, in the process chamber 201, the processing region A serving as a first region to which the gas is supplied through the process gas supply structure 212 and the heat insulating region B serving as a second region different from the first region are present. The processing region A serving as the first region functions as a substrate processing region where the substrate S is processed, that is, the substrates S are processed. In addition, when the substrate retainer 300 is loaded as described later, the processing region A (that is, the substrate processing region) may serve as a substrate accommodating region corresponding to a region where the substrates S are supported (or held) by the substrate retainer 300. On the other hand, the heat insulating region B serving as the second region may function as a heat insulating region for the heat insulator 502 (which is described later) provided below the substrate retainer 300.

In addition, the processing region A and the heat insulating region B are arranged so as to be in contact with each other in the reaction tube 210. However, the processing region A and the heat insulating region B are not limited thereto. For example, the processing region A and the heat insulating region B may be separated from each other, or may be arranged such that the processing region A and the heat insulating region B overlap at least partially.

### <Process Gas Supply Structure>

The process gas supply structure 212 is connected to each of a gas supply pipe 251 and a gas supply pipe 261. In addition, the process gas supply structure 212 includes a distributor (which is a distribution structure) 125 configured to distribute gases supplied through each gas supply pipe mentioned above. The nozzle 223 and the nozzle 224 are provided at a downstream side of the distributor 125. The nozzles 223 and the nozzles 224 are connected to a downstream side of the gas supply pipe 251 and a downstream side of the gas supply pipe 261, respectively, via the distributor 125. The nozzles 223 and the nozzles 224 are arranged side by side substantially in the horizontal direction. In addition, the nozzles 223 and the nozzles 224 are arranged in the vertical direction at positions corresponding to the substrates S. The process gas is supplied from beside (that is, a side of) the substrate S while the substrate S is in the process chamber 201.

The distributor 125 is configured such that each gas can be supplied to the nozzles 223 through the gas supply pipe 251 and to the nozzles 224 through the gas supply pipe 261. For example, a gas flow path can be provided for each combination of the gas supply pipe and the nozzles corresponding to the gas supply pipe. Thereby, since the gases respectively supplied through the gas supply pipes mentioned above are not mixed, it is possible to suppress a generation of reaction by-products (also referred to as “particles”) that may be generated when the gases are mixed in the distributor 125.

### <Upstream Side Gas Guide and Downstream Side Gas Guide>

The upstream side gas guide 214 is disposed between the process gas supply structure 212 and the reaction tube 210.

The upstream side gas guide 214 includes a housing 227 and a plurality of partition plates 226. Hereafter, each of the partition plates 226 may also be simply referred to as a “partition plate 226”. The partition plate 226 extends in the horizontal direction. The “horizontal direction” of the partition plate 226 may refer to a direction toward a side wall of the housing 227. The partition plates 226 are arranged in the vertical direction. The partition plate 226 is fixed to the side wall of the housing 227 such that it is possible to prevent the gas from flowing beyond the partition plate 226 into an adjacent region below or above the partition plate 226. By preventing the gas from flowing beyond the partition plate 226, it is possible to reliably form a gas flow described later.

The partition plates 226 are provided at positions corresponding to the substrates S, respectively. The nozzles 223 and the nozzles 224 are disposed between adjacent partition plates 226 and between the partition plate 226 and the housing 227.

The gas ejected through the nozzle 223 or the nozzle 224 is supplied to a surface of the substrate S. That is, when viewed from the substrate S, the gas is supplied along a lateral direction of the substrate S. Since the partition plate 226 is a continuous structure extending in the horizontal direction and provided without a hole, a mainstream of the gas is restrained from flowing in the vertical direction and flows in the horizontal direction. Therefore, a pressure loss of the gas reaching each substrate S can be uniformized along the vertical direction.

The downstream side gas guide 215 is disposed downstream of the reaction tube 210 in the gas flow direction, that is, between the reaction tube 210 and the gas exhaust structure 213.

The downstream side gas guide 215 is configured such that a ceiling thereof is provided above an uppermost substrate among the substrates S when the substrates S are supported by the substrate retainer 300 serving as the substrate support configured to support the substrates S and such that a bottom thereof is provided below a lowermost substrate among the substrates S when the substrates S are supported by the substrate retainer 300.

The downstream side gas guide 215 includes a housing 231 and a plurality of partition plates 232. Hereafter, each of the partition plates 232 may also be simply referred to as a “partition plate 232”. The partition plate 232 extends in the horizontal direction. The “horizontal direction” of the partition plate 232 may refer to a direction toward a side wall of the housing 231. The partition plates 232 are arranged in the vertical direction. The partition plate 232 is fixed to the side wall of the housing 231 such that it is possible to prevent the gas from flowing beyond the partition plate 232 into an adjacent region below or above the partition plate 232. By preventing the gas from flowing beyond the partition plate 232, it is possible to reliably form the gas flow described later.

The upstream side gas guide 214 communicates with a space within the downstream side gas guide 215 via the process chamber 201. A height of a ceiling of the housing 227 is configured to be the same as that of a ceiling of the housing 231. In addition, a bottom of the housing 227 is provided above a bottom of the housing 231.

The partition plates 232 are provided at positions corresponding to the substrates S and corresponding to the partition plates 226, respectively. It is preferable that the partition plate 226 and the partition plate 232 corresponding to the partition plate 226 are provided at the same height. In addition, when processing the substrate S, it is preferable that the substrate S, the partition plate 226 corresponding to the substrate S and the partition plate 232 corresponding to the partition plate 226 are provided at the same height. With such a structure, the gas flow in the horizontal direction passing over the substrate S and the partition plate 232 is formed by the gas supplied through each nozzle, as shown by each arrow in FIG. 1. By configuring the partition plate 232 as described above, it is possible to uniformize the pressure loss of the gas ejected (or discharged) through each of the substrates S. Therefore, the flow of the gas passing through each of the substrates S is formed in the horizontal direction toward the gas exhaust structure 213 while suppressing a gas flow in the vertical direction.

By providing the partition plates 226 and the partition plates 232, it is possible to uniformize the pressure loss in the vertical direction at both an upstream and a downstream of each of the substrates S. As a result, it is possible to reliably form a horizontal gas flow over the partition plate 226, the substrate S and the partition plate 232 while suppressing a vertical gas flow.

That is, the partition plates 226 are provided corresponding to the substrates S, respectively, and spaces partitioned by the housing 227 and the partition plates 226 are used as a plurality of gas supply holes through which the process gas is supplied toward an upper surface of each substrate S. In addition, the partition plates 232 are provided corresponding to the substrates S, respectively, and spaces partitioned by the housing 231 and the partition plates 232 are used as a plurality of second exhaust holes communicating between the process chamber 201 and an exhaust pipe 281. By providing the gas supply holes and the second exhaust holes in a manner corresponding to the substrates S in a manner described above, it is possible to improve a processing uniformity on the plurality of substrates S.

### <Gas Exhaust Structure>

The gas exhaust structure 213 is provided downstream of the downstream side gas guide 215. The gas exhaust structure 213 is constituted mainly by a housing 241 and an exhaust hole 244. The gas exhaust structure 213 is provided with a buffer structure 242 serving as a space where the gases exhausted through the second exhaust holes of the partition plates 232 join together and are exhausted by a gas exhaust system 280 described later. Thereby, a flow rate of each gas exhausted through each of the second exhaust holes is uniformized by the buffer structure 242. As a result, it is possible to improve the processing uniformity on the plurality of substrates S. The exhaust hole 244 is provided at a downstream side of the housing 241 on a lower portion of the housing 241 in the horizontal direction. The exhaust pipe 281 is connected to the process chamber 201 via the exhaust hole 244.

The gas exhaust structure 213 communicates with the space within the downstream side gas guide 215. The housing 231 and the housing 241 may form a structure with a continuous height. That is, a height of the ceiling of the housing 231 is configured to be the same as that of a ceiling of the housing 241, and a height of the bottom of the housing 231 is configured to be the same as that of a bottom of the housing 241.

The gas exhaust structure 213 is provided in a lateral direction of the reaction tube 210, and is a lateral exhaust structure configured to exhaust the gas along the lateral direction of the substrate S.

A bottom surface of the housing 231 is configured such that a thermocouple 500 can be installed thereon. By configuring the bottom of the housing 231 below the bottom of the housing 227 and configuring the space within the downstream side gas guide 215 to be wider than a space within the upstream side gas guide 214, it is possible to secure a place for thermocouple 500 to be installed thereat, thereby preventing an inert gas supplied to the heat insulator 502 or an atmosphere (including the reaction by-products) of the heat insulating region B from flowing into the processing region A. Therefore, the flow of the gas passing through each of the substrates S is formed in the horizontal direction toward the gas exhaust structure 213 while suppressing the gas flow in the vertical direction.

That is, the gas that has passed through the downstream side gas guide 215 is exhausted through the exhaust hole 244. When the gas is exhausted through the exhaust hole 244, since the gas exhaust structure 213 is not provided with a structure similar to the partition plate described above, the gas flow whose vertical component is non-zero is formed toward the exhaust hole 244.

### <Substrate Retainer>

The substrate retainer 300 accommodated (or housed) in the reaction tube 210 includes a partition plate retainer (which is partition plate holder) 310 and a base structure 311.

A plurality of partition plates 314 of a disk shape are fixed to the partition plate retainer 310 at a predetermined pitch therebetween. Hereafter, each of the partition plates 314 may also be referred to as a “partition plate 314”. The substrates S are placed between the partition plates 314 at a predetermined interval therebetween. The partition plate 314 related to the substrate S may be arranged directly below the substrate S. The partition plates 314 may be provided above and/or below the substrate S. The partition plates 314 are configured to separate spaces between adjacent substrates among the substrates S from one another.

The substrates S are stacked and placed on the substrate retainer 300 at the predetermined interval therebetween in the vertical direction. The predetermined interval between the substrates S (that is, adjacent substrates) placed on the substrate retainer 300 is the same as a vertical interval (that is, the pitch described above) between the partition plates 314 (that is, adjacent partition plates) fixed to the partition plate retainer 310. In addition, a diameter of the partition plate 314 is set to be larger than a diameter of the substrate S.

The substrate retainer 300 is configured to support a plurality of substrates (for example, 5 substrates) as the substrates S in a multistage manner in the vertical direction. By simultaneously (collectively) processing the plurality of substrates S in a manner described above, it is possible to improve the productivity. In addition, the present embodiments will be described by way of an example in which 5 substrates are supported by the substrate retainer 300 as the substrates S. However, the present embodiments are not limited thereto. For example, the substrate retainer 300 may be configured to be capable of supporting (or holding) from 5 substrates to 50 substrates as the substrates S.

In addition, in the present specification, a notation of a numerical range such as “from 5 substrates to 50 substrates” means that a lower limit and an upper limit are included in the numerical range. Therefore, for example, a numerical range “from 5 substrates to 50 substrates” means a range equal to or higher than 5 substrates and equal to or lower than 50 substrates. The same also applies to other numerical ranges described in the present specification.

By loading the substrate retainer 300 mentioned above into the process chamber 201, the substrate S supported by the substrate retainer 300 can be placed in the processing region A in the process chamber 201. Then, a process of forming a film can be performed on the surface of the substrate S. In addition, in the transfer chamber 217 which will be described in detail later, the substrate S supported by the substrate retainer 300 can be replaced with another substrate S by a vacuum transfer robot (not shown) through a substrate loading/unloading port (not shown). Then, the above-mentioned another substrate S can be transferred into the reaction tube 210, and the process of forming the film can be performed on a surface of the above-mentioned another substrate S. For example, the substrate loading/unloading port is provided in a side wall of the transfer chamber 217.

### <Heat Insulator>

The heat insulator 502 is provided below the substrate retainer 300 in the reaction tube 210.

The heat insulator 502 is constituted by a hollow vessel whose outer wall surface (that is, an outer surface) is of a cylindrical shape, and is configured to function as a heat insulating material by a hollow structure thereof. By disposing the heat insulator 502 below the substrate retainer 300, it is possible to suppress a temperature decrease of the substrate S provided at a lower portion of the substrate retainer 300. Therefore, it is possible to improve the processing uniformity on the plurality of substrates S, and it is also possible to improve a processing uniformity within the surface of the substrate S.

The heat insulator 502 is supported by a support 441. A support structure 440 capable of supporting the substrate retainer 300 penetrates a center of the support 441 in a manner concentric with the support 441.

A gas supply hole 291 is provided below the process chamber 201 of the reaction tube 210. More specifically, the gas supply hole 291 is provided in a wall of the reaction tube 210 (that is, the process chamber 201) beside the heat insulator 502 and below an upper end of the heat insulator 502 when the substrate retainer 300 is loaded into the reaction tube 210. A gas supply pipe 292 is connected to the gas supply hole 291. The inert gas is supplied through the gas supply pipe 292, and the gas supply pipe 292 is configured such that the inert gas is supplied through a side of the heat insulator 502 to a space between an inner wall surface of the reaction tube 210 (that is, the process chamber 201) and the outer surface of the heat insulator 502. In other words, the gas supply hole 291 and the gas supply pipe 292 are provided in a lower portion of the process chamber 201, and constitute a second gas supplier configured to supply the gas from the lower portion of the process chamber 201 to the heat insulating region B serving as the second region.

The gas supply hole 291 and the gas supply pipe 292 constituting the second gas supplier are provided at positions opposite to the gas exhaust structure 213 serving as a part of the exhauster, with the reaction tube 210 (that is, the process chamber 201) interposed therebetween.

### <Transfer Chamber>

The transfer chamber 217 disposed below the reaction tube storage chamber 206 is installed via the manifold 216 located below the reaction tube 210. In the transfer chamber 217, the substrate S may be transferred to (or placed on) the substrate retainer (hereinafter, may also be simply referred to as a “boat”) 300 by the vacuum transfer robot via the substrate loading/unloading port, or the substrate S may be transferred (or taken) out of the substrate retainer 300 by the vacuum transfer robot.

Inside the transfer chamber 217, a vertical driver (which is a vertical driving structure) 400 constituting a first driver (first driving structure) configured to drive the substrate retainer 300 and the partition plate retainer 310 in an up-down direction (vertical direction) can be accommodated (or stored). FIG. 1 shows a state in which the substrate retainer 300 is elevated by the vertical driver 400 and stored in the reaction tube 210. In addition, while the substrate retainer 300 is accommodated in the reaction tube 210, the heat insulator 502 is disposed at a lower portion of the reaction tube 210 such that the heat insulator 502 is configured to form the heat insulating region B provided below the process chamber 201. Thereby, it is possible to reduce a thermal conduction to the transfer chamber 217 from the process chamber 201.

The vertical driver 400 may include: a rotational driver (which is a rotational driving structure) 430 configured to rotate the substrate retainer 300 and the partition plate retainer 310 together; and a boat vertical driver (which is a boat vertical driving structure) 420 configured to drive the substrate retainer 300 in the up-down direction (vertical direction) relative to the partition plate retainer 310.

The rotational driver 430 and the boat vertical driver 420 are fixed to a base flange 401 serving as a lid supported by a side plate 403 on a base plate 402.

An O-ring 446 is installed on an upper surface of the base flange 401, and as shown in FIG. 1, by driving a vertical driving motor 410 such that the upper surface of the base flange 401 is elevated to a position where it is pressed against the transfer chamber 217, it is possible to maintain the inside of the reaction tube 210 airtight.

In addition, a hole 401a is provided in a center of the base flange 401 such that the support structure 440 configured to support the heat insulator 502 from thereunder and the support 441 that configured to support the substrate retainer 300 from thereunder pass through the hole 401a. In addition, an annular space is provided between the hole 401a and the support structure 440. A gas supply pipe 701 is connected to the annular space. The inert gas is supplied through the gas supply pipe 701, and the gas supply pipe 701 is configured such that the inert gas is supplied from below the heat insulator 502 to a location such as the upper surface of the base flange 401 and a periphery of the support structure 440.

### <Gas Supply System>

Subsequently, a gas supply system will be described in detail.

The gas supply system includes: a process gas supply system configured to supply the gas (that is, the process gas) to the processing region A; and an inert gas supply system 270 configured to supply the gas (that is, the inert gas) to the heat insulating region B. The process gas supply system is configured to supply the process gas serving as a first gas to the processing region A, and functions as the first gas supplier together with the process gas supply structure 212 described above. The inert gas supply system 270 is configured to supply the inert gas serving as a second gas to the heat insulating region B, and functions as the second gas supplier together with the gas supply hole 291 and the gas supply pipe 292 described above. The inert gas supply system 270 serving as the second gas supplier is provided in the lower portion of the process chamber 201, and is configured to supply the inert gas from the lower portion of the process chamber 201.

In addition, the process gas supply system includes: a first process gas supply system 250 configured to supply the gas through the gas supply pipe 251; and a second process gas supply system 260 configured to supply the gas through the gas supply pipe 261.

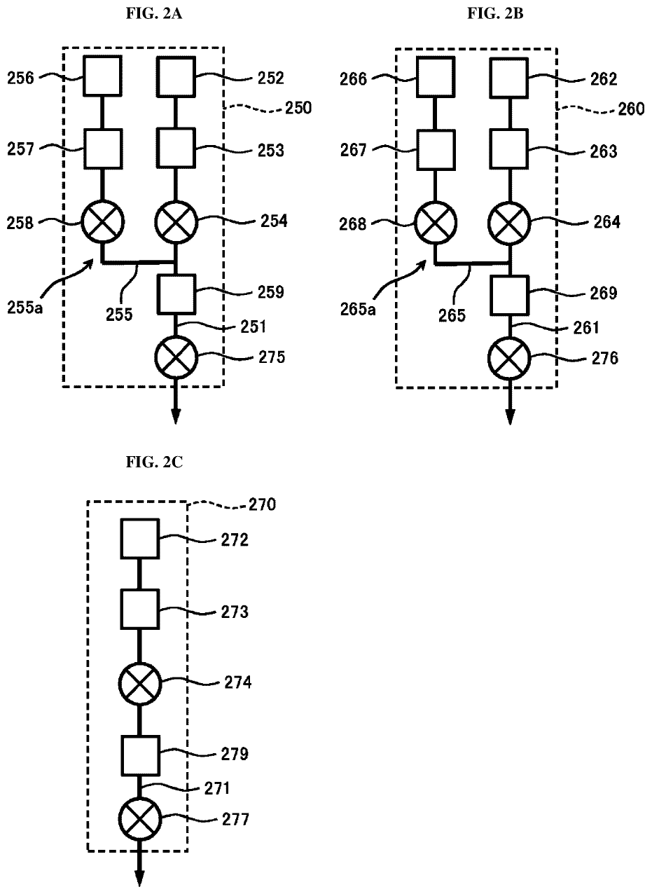

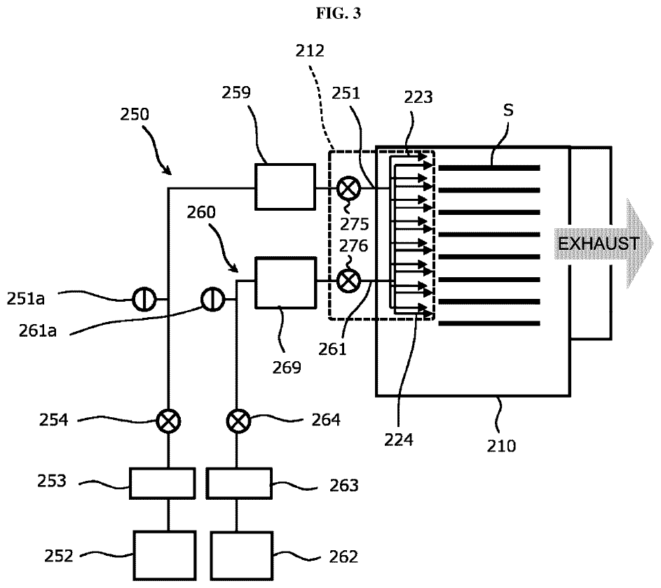

Hereinafter, such gas supply systems will be described in order with reference to FIGS. 2 and 3.

### <First Process Gas Supply System>

The first process gas supply system 250 in the process gas supply system (that is, the first gas supplier) is configured to supply the gas to the processing region A through the gas supply pipe 251. Therefore, as shown in FIGS. 2A and 3, a first gas supply source 252, a mass flow controller (MFC) 253 serving as a flow rate controller (a flow rate control structure), a valve 254 serving as an opening/closing valve, a tank 259 serving as a storage configured to store the gas and a valve 275 are sequentially installed at the gas supply pipe 251 in this order from an upstream side to a downstream side of the gas supply pipe 251 in a gas flow direction. Hereinafter, the tank 259 may also be referred to as a “first flash tank 259”. A digital gauge 251a may be connected to the gas supply pipe 251.

The first gas supply source 252 is a source of a first process gas containing a first element (also referred to as a “first element-containing gas”). The first element-containing gas serves as a source gas, that is, one of process gases.

The first process gas supply system 250 is constituted mainly by the gas supply pipe 251, the MFC 253, the valve 254, the first flash tank 259 and the valve 275. The first process gas supply system 250 may also be referred to as a “silicon-containing gas supplier”. The first process gas supply system 250 may further include the first gas supply source 252.

A gas supply pipe 255 is connected to the gas supply pipe 251 at a downstream side of the valve 254 and an upstream side of the first flash tank 259. An inert gas supply source 256, an MFC 257 and a valve 258 are sequentially installed at the gas supply pipe 255 in this order from an upstream side to a downstream side of the gas supply pipe 255 in the gas flow direction. For example, the inert gas such as nitrogen (N₂) gas is supplied from the inert gas supply source 256.

An inert gas supplier 255a is constituted mainly by the gas supply pipe 255, the MFC 257 and the valve 258. The inert gas supplied from the inert gas supply source 256 acts as a purge gas for purging the gas remaining in the reaction tube 210 when performing a substrate processing described later. The inert gas supplier 255a may further include the inert gas supply source 256. The first process gas supply system 250 may further include the inert gas supplier 255a.

### <Second Process Gas Supply System>

The second process gas supply system 260 in the process gas supply system (that is, the first gas supplier) is configured to supply the gas to the processing region A through the gas supply pipe 261. Therefore, as shown in FIGS. 2B and 3, a second gas supply source 262, a mass flow controller (MFC) 263, a valve 264, a tank 269 serving as a storage configured to store the gas and a valve 276 are sequentially installed at the gas supply pipe 261 in this order from an upstream side to a downstream side of the gas supply pipe 261 in the gas flow direction. Hereinafter, the tank 269 may also be referred to as a “second flash tank 269”. A digital gauge 261a may be connected to the gas supply pipe 261.

The second gas supply source 262 is a source of a second process gas containing a second element (hereinafter, also referred to as a “second element-containing gas”). The second process gas serves as one of the process gases. In addition, the second process gas may serve as a reactive gas or a modification gas.

The second process gas supply system 260 is constituted mainly by the gas supply pipe 261, the MFC 263, the valve 264, the second flash tank 269 and the valve 276. The second process gas supply system 260 may further include the second gas supply source 262.

A gas supply pipe 265 is connected to the gas supply pipe 261 at a downstream side of the valve 264. An inert gas supply source 266, an MFC 267 and a valve 268 are sequentially installed at the gas supply pipe 265 in this order from an upstream side to a downstream side of the gas supply pipe 265 in the gas flow direction. For example, the inert gas such as nitrogen (N₂) gas is supplied from the inert gas supply source 266.

An inert gas supplier 265a is constituted mainly by the gas supply pipe 265, the MFC 267 and the valve 268. The inert gas supplied from the inert gas supply source 266 acts as the purge gas for purging the gas remaining in the reaction tube 210 when performing the substrate processing described later. The inert gas supplier 265a may further include the inert gas supply source 266. The second process gas supply system 260 may further include the inert gas supplier 265a.

### <Inert Gas Supply System>

The inert gas supply system 270 (that is, the second gas supplier) is configured to supply the gas (that is, the inert gas) to the heat insulating region B through the gas supply pipe 292 connected thereto. Therefore, as shown in FIG. 2C, an inert gas supply source 272, a mass flow controller (MFC) 273, a valve 274, a tank 279 serving as a storage configured to store the gas and a valve 277 are sequentially installed at a gas supply pipe 271 in this order from an upstream side to a downstream side of the gas supply pipe 271 in the gas flow direction. Hereinafter, the tank 279 may also be referred to as a “third flash tank 279”. For example, the inert gas such as the nitrogen (N₂) gas is supplied from the inert gas supply source 272.

The inert gas supply system 270 is constituted mainly by the gas supply pipe 271, the MFC 273, the valve 274, the third flash tank 279 and the valve 277. The inert gas supply system 270 may further include the inert gas supply source 272. The inert gas supply system 270 is configured to supply the inert gas toward the heat insulating region B in which the heat insulator 502 is provided. The inert gas supplied from the inert gas supply source 272 acts as the purge gas capable of purging an inside (inner portion) and a periphery of the heat insulator 502 constituting the heat insulating region B disposed below the process chamber 201 when the substrate retainer 300 is loaded into the process chamber 201.

In addition, the inert gas supply system 270 also includes a configuration (not shown) for the gas supply pipe 701 similar to that for the gas supply pipe 292. That is, the inert gas supply system 270 is configured to be capable of supplying the inert gas through the gas supply pipe 701, and capable of purging the inside and the periphery of the heat insulator 502 constituting the heat insulating region B disposed below the process chamber 201.

### <Exhaust System (Gas Exhaust System)>

Subsequently, the gas exhaust system 280 will be described with reference to FIG. 1.

The gas exhaust system 280 functions as the exhauster configured to exhaust an atmosphere (inner atmosphere) of the reaction tube 210 through the exhaust pipe 281, together with the gas exhaust structure 213 mentioned above. Therefore, as shown in FIG. 1, a vacuum pump 284 serving as a vacuum exhaust apparatus is connected to the exhaust pipe 281 via a valve 282 and an APC (Automatic Pressure Controller) valve 283 serving as a pressure regulator (which is a pressure adjusting structure). That is, the gas exhaust system 280 is configured to be capable of vacuum-exhausting the reaction tube 210 such that a pressure (inner pressure) of the reaction tube 210 reaches and is maintained at a predetermined pressure (vacuum degree).

The gas exhaust system 280 serving as a part of the exhauster configured to exhaust the gas in the process chamber 201 is constituted by the exhaust pipe 281, the valve 282 and the APC valve 283. In addition, the gas exhaust system 280 may further include the vacuum pump 284. That is, the gas exhaust system 280 includes the exhaust pipe 281 communicating with the process chamber 201 of the reaction tube 210, and is configured to exhaust an atmosphere (inner atmosphere) of the process chamber 201 through the exhaust pipe 281. The gas exhaust system 280 is configured to be capable of exhausting the process gas along a direction away from the side of the reaction tube 210 from which the process gas is supplied.

In addition, the gas exhaust system 280 is configured to exhaust the inner atmosphere of the process chamber 201. In addition to an atmosphere of the process gas supplied to the processing region A through the first process gas supply system 250 and the second process gas supply system 260 (which are the process gas supply system), the inner atmosphere of the process chamber 201 may include an atmosphere of the inert gas supplied to the heat insulating region B through the inert gas supply system 270 via the gas supply pipes 292 and 701.

That is, the process gas supplied to the processing region A in atmosphere of the process chamber 201 and the inert gas supplied to the heat insulating region B in atmosphere of the process chamber 201 are respectively exhausted via the first exhaust pipe 281.

### <Controller>

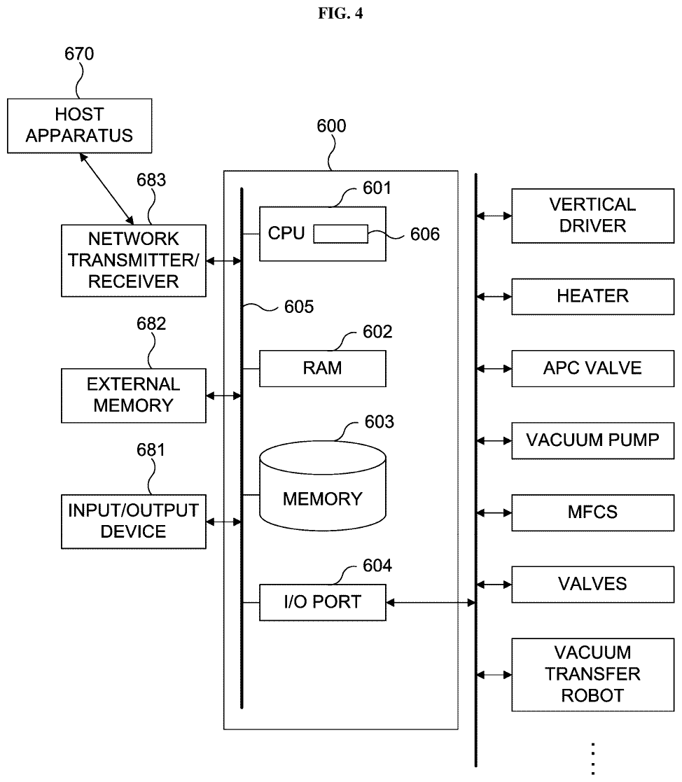

Subsequently, a controller 600 serving as a control structure (control apparatus) of the substrate processing apparatus 10 will be described with reference to FIG. 4.

The substrate processing apparatus 10 includes the controller 600 configured to control operations of components constituting the substrate processing apparatus 10.

The controller 600 may be constituted by a computer including a CPU (Central Processing Unit) 601, a RAM (Random Access Memory) 602, a memory 603 serving as a memory structure and an I/O port (input/output port) 604. The RAM 602, the memory 603 and the I/O port 604 are configured to be capable of exchanging data with the CPU 601 via an internal bus 605. The transmission/reception of the data in the substrate processing apparatus 10 may be performed by an instruction from a transmission/reception instruction controller 606 which is one of functions of the CPU 601.

A network transmitter/receiver 683 connected to a host apparatus 670 via a network is provided at the controller 600. For example, the network transmitter/receiver 683 is capable of receiving data such as information regarding a processing history and a processing schedule for the substrate S stored in a pod from the host apparatus 670.

For example, the memory 603 may be embodied by a component such as a flash memory and an HDD (Hard Disk Drive). The memory 603 is configured to store process conditions for each type of substrate processing. That is, a control program for controlling an operation of the substrate processing apparatus 10 or a process recipe in which information such as procedures and conditions of the substrate processing is stored may be readably stored in the memory 603.

The process recipe is obtained by combining steps (procedures) of the substrate processing described later to obtain a predetermined result by performing the steps of the substrate processing described later by the controller 600, and acts as a program. Hereinafter, the process recipe and the control program may be collectively or individually referred to simply as a “program”. Thus, in the present specification, the term “program” may refer to the process recipe alone, may refer to the control program alone, or may refer to both of the process recipe and the control program. The RAM 602 serves as a memory area (work area) in which the program or the data read by the CPU 601 is temporarily stored.

The I/O port 604 is electrically connected to the components of the substrate processing apparatus 10 described above.

The CPU 601 is configured to read and execute the control program from the memory 603, and is configured to read the process recipe from the memory 603 in accordance with an instruction such as an operation command inputted from an input/output device 681. The CPU 601 is configured to be capable of controlling the substrate processing apparatus 10 in accordance with contents of the process recipe read from the memory 603. The CPU 601 is further configured to be capable of controlling a supply amount and a supply timing of the gas when the gas is supplied to a location such as the processing region A and the heat insulating region B, in accordance with the type and the conditions of the substrate processing.

The CPU 601 includes the transmission/reception instruction controller 606. For example, the controller 600 according to the present embodiments may be embodied by preparing an external memory 682 (for example, a magnetic disk such as a hard disk, an optical disk such as a DVD, a magneto-optical disk such as an MO, a semiconductor memory such as a USB memory) storing the program described above and by installing the program onto the computer by using the external memory 682. Further, a method of providing the program to the computer is not limited to a method using the external memory 682. For example, the program may be directly provided to the computer by a communication interface such as the Internet and a dedicated line instead of the external memory 682. In addition, the memory 603 and the external memory 682 may be embodied by a non-transitory computer-readable recording medium. Hereinafter, the memory 603 and the external memory 682 may be collectively or individually referred to as a “recording medium”. Thus, in the present specification, the term “recording medium” may refer to the memory 603 alone, may refer to the external memory 682 alone, or may refer to both of the memory 603 and the external memory 682.

### (2) Procedures of Substrate Processing (Substrate Processing Method)

Hereinafter, as a part of a manufacturing process of a semiconductor device (that is, a method of manufacturing the semiconductor device), the substrate processing will be described by way of an example in which a film forming process of forming the film on the substrate S is performed by using the substrate processing apparatus 10 described above. In addition, in the following description, the controller 600 controls the operations of the components constituting the substrate processing apparatus 10.

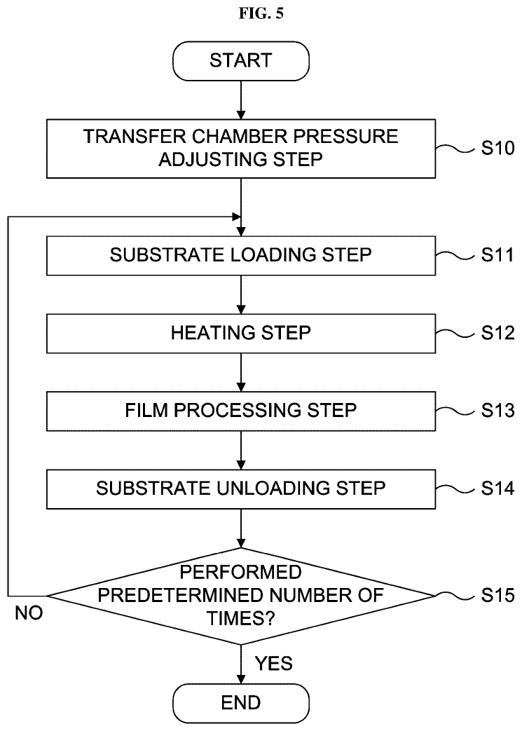

Hereinafter, the film forming process will be described with reference to FIG. 5 by way of an example in which the film is formed on the substrate S by using the first process gas and the second process gas as the process gases and by alternately supplying the first process gas and the second process gas.

In the present specification, the term “substrate” may refer to “a substrate itself”, or may refer to “a substrate and a stacked structure (aggregated structure) of a predetermined layer (or layers) or a film (or films) formed on a surface of the substrate”. In the present specification, the term “a surface of a substrate” may refer to “a surface of a substrate itself”, or may refer to “a surface of a predetermined layer (or a predetermined film) formed on a substrate”. Thus, in the present specification, “forming a predetermined layer (or a film) on a substrate” may refer to “forming a predetermined layer (or a film) directly on a surface of a substrate itself”, or may refer to “forming a predetermined layer (or a film) on a surface of another layer (or another film) formed on a substrate”. In the present specification, the terms “substrate” and “wafer” may be used as substantially the same meaning.

### <Transfer Chamber Pressure Adjusting Step S10>

First, a transfer chamber pressure adjusting step S10 will be described. In the present step, a pressure (inner pressure) of the transfer chamber 217 is set to the same level as that of a vacuum transfer chamber (not shown) provided adjacent to the transfer chamber 217.

### <Substrate Loading Step S11>

Subsequently, a substrate loading step S11 will be described. When the inner pressure of the transfer chamber 217 reaches and is maintained at the vacuum level, a transfer of the substrate S is started. When the substrate S reaches the vacuum transfer chamber, a gate valve (not shown) related thereto is opened. Then, the substrate S is loaded (transferred) into the transfer chamber 217 by the vacuum transfer robot.

In the present step, the substrate retainer 300 stands by in the transfer chamber 217, and the substrate S is transferred to the substrate retainer 300. When a predetermined number of the substrates S are transferred to the substrate retainer 300, the vacuum transfer robot is retracted, and the substrate retainer 300 is elevated by the vertical driver 400 to move the substrates S into the process chamber 201 in the reaction tube 210. The substrates S are moved into the process chamber 201 while stacked in the vertical direction.

When moving the substrate S to the reaction tube 210, the surface of the substrate S is positioned so as to be aligned at the same height as the partition plate 226 and the partition plate 232.

### <Heating Step S12>

Subsequently, a heating step S12 will be described. When the substrate S is loaded into the process chamber 201 in the reaction tube 210, the inner pressure of the reaction tube 210 is controlled (adjusted) to a predetermined pressure and a surface temperature of the substrate S is controlled by the heater 211 to a predetermined temperature. For example, the heater 211 heats the substrate S such that the surface temperature of the substrate S is set to a temperature 400° C. or higher and 800° C. or lower, and preferably 500° C. or higher and 700° C. or lower. For example, the predetermined pressure may be set to a pressure within a range from 50 Pa to 5,000 Pa.

### <Film Processing Step S13>

Subsequently, a film processing step S13 will be described. In the film processing step S13, by supplying the gases to the substrate S in accordance with the process recipe while the substrates S are stacked on the substrate retainer 300 and accommodated in the process chamber 201, it is possible to form a desired film on the substrate S.

For example, when an alternating supply process is performed to supply the gases, a first step of supplying the first process gas into the reaction tube 210, a second step of supplying the inert gas into the reaction tube 210 and exhausting the inner atmosphere of the reaction tube 210, a third step of supplying the second process gas into the reaction tube 210, and a fourth step of supplying the inert gas into the reaction tube 210 and exhausting the inner atmosphere of the reaction tube 210 are sequentially performed in this order. Then, by performing a combination of each step a plurality number of times, it is possible to form the desired film on the substrate S.

The gas supplied as described above forms the gas flow along the upstream side gas guide 214, a space above the substrate S and the downstream side gas guide 215. In such a state, since the gas is supplied to each of the substrates S without the pressure loss on each of the substrates S, it is possible to uniformly perform the substrate processing between the substrates S.

In addition, in the film processing step S13, the gas is supplied to the substrate S by a so-called “flash supply”. The flash supply will be described in detail later.

### <Substrate Unloading Step S14>

Subsequently, a substrate unloading step S14 will be described. In the substrate unloading step S14, the substrate S processed as described above is transferred (unloaded) out of the transfer chamber 217 in an order reverse to that of the substrate loading step S11.

### <Determination Step S15>

Subsequently, a determination step S15 will be described. In the present step, it is determined whether or not the processing of the substrate S described above (that is, the steps S11 to S14) has been performed a predetermined number of times. When it is determined that the processing has not been performed the predetermined number of times, the substrate loading step S11 is performed again to process a subsequent substrate S to be processed. When it is determined that the processing has been performed the predetermined number of times, the substrate processing is terminated.

While the present embodiments are described by way of an example in which the horizontal gas flow is formed, it is sufficient as long as a main flow of the gas is generally formed in the horizontal direction. For example, a gas flow may be diffused in the vertical direction as long as it does not affect a uniform processing of the plurality of substrates.

In addition, in the above, various expressions such as “the same”, “equal”, “similar” and the like are used. However, it goes without saying that the expressions described above mean “substantially the same”.

(3) Control Process when Gas is Supplied

Subsequently, procedures when the gas is supplied into the reaction tube 210 (that is, the process chamber 201) in the film processing step S13 of the substrate processing mentioned above will be described with reference to FIGS. 2A, 2B, 2C and 3.

In the film processing step S13, for example, when the alternating supply process is performed to supply the gases, as described above, the first step, the second step, the third step and the fourth step are sequentially performed in this order. In addition, at least in the first step and the third step among the steps mentioned above, the process gas is supplied to the substrate S in a flash-like manner (that is, the flash supply is performed). Each of the steps will be described in detail below.

### <First Step>

In the first step, first, the valve 254 is opened while the valve 275 is closed. Thereby, a gas charging of charging the first process gas (which is the source gas) into the first flash tank 259 is performed. The gas charging into the first flash tank 259 is performed until a charging amount of the first process gas reaches an amount within a range from 30 kPa to 50 kPa when a tank capacity of the first flash tank 259 is 1,000 cc, for example. The gas charging may be performed in advance before the first step is started.

Then, after the first process gas is charged into the first flash tank 259, the valve 275 is opened. As a result, the first process gas stored in the first flash tank 259 is supplied to the process chamber 201 at a large flow rate in a short time. In a manner described above, in the first step, the first process gas is supplied in a flash-like manner.

In the present step, while the first process gas is being supplied into the process chamber 201, the valve 254 may be open or closed. In addition, the valve 258 may be opened to supply the inert gas such as the N₂ gas into the gas supply pipe 251 through the gas supply pipe 255. In addition, in order to prevent the first process gas from entering the gas supply pipe 261, the valve 268 may be opened to supply the inert gas into the gas supply pipe 261.

The first process gas supplied into the process chamber 201 is supplied to the substrate S in the horizontal direction from beside (that is, the side of) the substrate S through the gas supply structure 212, and exhausted through the exhaust pipe 281.

In the present step, the APC valve 283 is adjusted such that the inner pressure of the reaction tube 210 is set to be a pressure within a range from 1 Pa to 3,990 Pa. In the following, for example, a temperature of the heater 211 configured to heat the substrate S is adjusted such that a temperature of the substrate S reaches and is maintained at a temperature within a range from 100° C. to 1,500° C., preferably from 400° C. to 800° C.

In other words, in the process chamber 201, while the substrate S loaded into the process chamber 201 is heated, the first process gas is supplied to the processing region A for the substrate S, and the valve 282 is opened to exhaust the first process gas through the exhaust pipe 281. In such a state, the inert gas is supplied to the heat insulating region B below the processing region A by the inert gas supply system 270, as will be described later in detail.

As the first process gas supplied to the processing region A, for example, a silicon (Si)-containing gas may be used. As the silicon-containing gas, for example, a gas such as hexachlorodisilane (Si₂Cl₆, abbreviated as HCDS) gas which is a gas containing silicon and chlorine (Cl) may be used.

### <Second Step>

In the second step (which is performed a predetermined time after the first step is started), the process chamber 201 is purged. Therefore, in the second step, with the valve 254 closed to stop a supply of the first process gas, the valves 258, 275, 268, 276, 274 and 277 and the like are opened to supply the inert gas serving as the purge gas into the gas supply pipes 255, 265, 271, 292 and 701. In addition, with the valve 282 and the APC valve 283 of the exhaust pipe 281 left open, the reaction tube 210 is vacuum-exhausted by the vacuum pump 284.

### <Third Step>

In the third step (which is performed a predetermined time after the second step is started), similar to the first step, first, the valve 264 is opened and the valve 276 is closed. Thereby, a gas charging of charging the second process gas (which is the reactive gas or the modification gas) into the second flash tank 269 is performed. The gas charging into the second flash tank 269 is performed until a charging amount of the second process gas reaches an amount within a range from 30 kPa to 50 kPa when a tank capacity of the second flash tank 269 is 1,000 cc, for example. The gas charging may be performed in advance before the first step is started.

Then, after the second process gas is charged into the second flash tank 269, the valve 276 is opened. As a result, the second process gas stored in the second flash tank 269 is supplied to the process chamber 201 at a large flow rate in a short time. In a manner described above, in the third step, the second process gas is supplied in a flash-like manner.

In the present step, while the second process gas is being supplied into the process chamber 201, the valve 264 may be open or closed. In addition, the valve 268 may be opened to supply the inert gas such as the N₂ gas into the gas supply pipe 261 through the gas supply pipe 265. In addition, in order to prevent the second process gas from entering the gas supply pipe 251, the valve 258 may be opened to supply the inert gas into the gas supply pipe 251.

The second process gas supplied into the process chamber 201 is supplied to the substrate S in the horizontal direction from beside (that is, the side of) the substrate S through the gas supply structure 212, and exhausted through the exhaust pipe 281.

In the present step, the APC valve 283 is adjusted such that the inner pressure of the reaction tube 210 is set to be a pressure within a range from 1 Pa to 3,990 Pa. In the following, for example, the temperature of the heater 211 configured to heat the substrate S is adjusted such that the temperature of the substrate S reaches and is maintained at a temperature within a range from 100° C. to 1,500° C., preferably from 400° C. to 800° C.

In other words, in the process chamber 201, while the substrate S loaded into the process chamber 201 is heated, the second process gas is supplied to the processing region A for the substrate S, and the valve 282 is opened to exhaust the second process gas through the exhaust pipe 281. In such a state, the inert gas is supplied to the heat insulating region B below the processing region A by the inert gas supply system 270, as will be described later in detail.

As the second process gas supplied to the processing region A, for example, the reactive gas (for example, a gas containing hydrogen (H) and nitrogen (N)) capable of reacting with the first process gas may be used. As the gas containing hydrogen and nitrogen, for example, a gas such as ammonia (NH₃) gas, diazene (N₂H₂) gas, hydrazine (N₂H₄) gas and N₃H₈ gas may be used.

### <Fourth Step>

In the fourth step (which is performed a predetermined time after the third step is started), the process chamber 201 is purged. Therefore, in the fourth step, with the valve 264 closed to stop a supply of the second process gas, the valves 258, 275, 268, 276, 274 and 277 and the like are opened to supply the inert gas serving as the purge gas into the gas supply pipes 255, 265, 271, 292 and 701. In addition, with the valve 282 and the APC valve 283 of the exhaust pipe 281 left open, the reaction tube 210 is vacuum-exhausted by the vacuum pump 284. As a result, it is possible to suppress a reaction between the first process gas and the second process gas in a gas phase in the reaction tube 210.

### <Repeatedly Performing Each Step>

A cycle (in which the first step to the fourth step described above are sequentially and non-simultaneously performed in this order) is performed a predetermined number of times (n times, where n is an integer of 1 or more). As a result, it is possible to form the film of a predetermined thickness on the substrate S. In the present embodiments, for example, a silicon nitride (SiN) film is formed.

In the first step and the third step among the first step to the fourth step, each of the first process gas and the second process gas supplied to the process chamber 201 forms the gas flow along the upstream side gas guide 214, the space above the substrate S and the downstream side gas guide 215. In such a state, since each of the first process gas and the second process gas is supplied to each of the substrates S without the pressure loss on each of the substrates S, it is possible to uniformly perform the substrate processing between the substrates S.

### <Gas Supply to Heat Insulating Region>

As described above, in the first step, the first process gas is supplied to the substrate S located in the processing region A. In addition, in the third step, the second process gas is supplied to the substrate S located in the processing region A. In such a case, when the inert gas is supplied to the heat insulating region B below the processing region A by the inert gas supply system 270, it is possible to prevent the first process gas, the second process gas and the reaction by-products from flowing into the heat insulating region B. Thereby, it is also possible to prevent the film from depositing on the heat insulator 502.

However, as described above, in the first step and the third step, the process gas is supplied in the flash-like manner (that is, the flash supply is performed). In such a case, in an initial stage of the flash supply, a pressure difference may occur between the processing region A and the heat insulating region B. For example, when a pressure (inner pressure) of the processing region A is set to be higher than a pressure (inner pressure) of the heat insulating region B, the process gas may flow down from the processing region A toward the heat insulating region B. As a result, it may not be possible to perform the processing of the substrates S uniformly.

Therefore, when the process gas (at least one among the first process gas and the second process gas, preferably both) is supplied in the flash-like manner, the inert gas is supplied to the heat insulating region B by the inert gas supply system 270 such that the pressure difference between the processing region A and the heat insulating region B is reduced. More specifically, when the process gas is supplied in the flash-like manner, in order to supply the inert gas such that the pressure difference between the processing region A and the heat insulating region B is reduced, the first process gas supply system 250 and the second process gas supply system 260 (which serve as the first gas supplier) and the inert gas supply system 270 (which serves as the second gas supplier) are controlled in accordance with a control instruction from the controller 600.

In the present specification, “the pressure difference is reduced” means that the pressure difference between the processing region A and the heat insulating region B does not exceed a predetermined allowable value (which is set in advance). In other words, “the pressure difference is reduced” means that the pressure difference between the processing region A and the heat insulating region B is equal to or less than the predetermined allowable value and that the pressure of the processing region A and the pressure of the heat insulating region B are recognized to be equal, and more preferably, the pressure of the processing region A and the pressure of the heat insulating region B are the same. In addition, for example, the predetermined allowable value is set such that the pressure difference between the processing region A and the heat insulating region B is within a range of from −10% to 10%. In a manner described above, it is possible to suppress a flow of the process gas supplied to the processing region A from being directed toward the heat insulating region B, and it is also possible to perform the processing of the substrates S uniformly. When the pressure difference falls below −10%, the inert gas flowing into the heat insulating region B may flow into the processing region A. Thereby, the process gas is diluted with the inert gas. As a result, the processing uniformity on the plurality of substrates S may deteriorate. In addition, when the pressure difference exceeds 10%, the process gas may flow into the heat insulating region B. As a result, by-products may adhere to a furnace opening such as the heat insulator 502 and the manifold 216. For example, the predetermined allowable value is not limited to such a value mentioned above, and may be set appropriately depending on conditions such as a relationship between the processing region A and the heat insulating region B.

Hereinafter, specific examples of a gas supply control for reducing the pressure difference between the processing region A and the heat insulating region B will be described.

### First Specific Example

When the inert gas is supplied to the heat insulating region B by the inert gas supply system 270, first, as shown in FIG. 2C, the valve 274 is opened and the valve 277 is closed. Thereby, a gas charging of charging the inert gas (which is the purge gas) into the third flash tank 279 is performed. The gas charging into the third flash tank 279 is performed until a charging amount of the inert gas reaches an amount within a range from 30 kPa to 50 kPa when a tank capacity of the third flash tank 279 is 1,000 cc, for example. The gas charging may be performed in advance before a supply of the inert gas is started.

Then, after the inert gas is charged into the third flash tank 279, the valve 277 is opened. As a result, the inert gas stored in the third flash tank 279 is supplied to the process chamber 201 at a large flow rate in a short time. In a manner described above, it is possible to perform the flash supply of the inert gas by the inert gas supply system 270 as in a case where the flash supply of the process gas is performed as described above.

The flash supply of the inert gas by the inert gas supply system 270 is performed in synchronization with the flash supply of the first process gas (which is the source gas) to the processing region A in the first step described above and in synchronization with the flash supply of the second process gas (which is the reactive gas or the modification gas) to the processing region A in the third step described above, as shown in FIG. 6. In other words, when the first process gas is supplied in the flash-like manner in the first step, the inert gas is supplied in the flash-like manner to the heat insulating region B in synchronization with the first process gas, and when the second process gas is supplied in the flash-like manner in the third step, the inert gas is supplied in the flash-like manner to the heat insulating region B in synchronization with the second process gas.

In the present specification, the term “in synchronization with” means that each flash supply is performed at the same timing, and specifically, includes a case where a discrepancy exists between timings of the flash supplies within an extent that can be considered substantially simultaneous (even though not perfectly simultaneous) in addition to a case where the flash supplies are started and ended simultaneously.

Therefore, the supply of the inert gas to the heat insulating region B is performed simultaneously (including a case where there is a discrepancy in timing that can be considered substantially simultaneous) with the flash supply of the process gas to the processing region A. In addition, the inert gas is also supplied at that time in the flash-like manner to the heat insulating region B.

In addition, the supply of the inert gas to the heat insulating region B is performed at a predetermined flow rate or a predetermined flow velocity. The predetermined flow rate or the predetermined flow velocity is set in advance such that the pressure difference between the processing region A and the heat insulating region B can be reduced.

For example, a flow rate of the process gas serving as the first gas is set to a flow rate within a range from 0.1 slm to 300 slm, preferably 0.3 slm to 200 slm, and more preferably 0.5 slm to 100 slm. The process gas includes the first process gas supplied in the first step and the second process gas supplied in the third step. A flow rate of the first process gas and a flow rate of the second process gas may be the same, or may be different from each other.

For example, with respect to the flow rate of the process gas, a flow rate of the inert gas serving as the second gas is set in accordance with a volume ratio of the processing region A to the heat insulating region B. For example, a volume of the processing region A is set to a volume within a range of from 1 L (liter) to 500 L, preferably from 5 L to 300 L, and more preferably from 10 L to 200 L. In addition, a volume of the heat insulating region B is set to a volume within a range of from 0.5 L to 300 L, preferably from 1 L to 200 L, and more preferably from 5 L to 100 L. Further, when the volume ratio of the processing region A to the heat insulating region B is between 1:1 and 10:1, for example, the flow rate of the inert gas is set to be a flow rate within a range of from 0.1 slm to 200 slm, preferably from 0.2 slm to 150 slm, and more preferably from 0.3 slm to 60 slm. In addition, when the flow rate of the first process gas supplied in the first step is different from the flow rate of the second process gas supplied in the third step (see FIG. 6), the flow rate of the inert gas supplied in the first step is different from the flow rate of the inert gas supplied in the third step in accordance with the flow rate of the first process gas and the flow rate of the second process gas.

When the gases are supplied to the processing region A and the heat insulating region B under such a gas supply control described above, even when the process gas is supplied in the flash-like manner to the processing region A, the inert gas is supplied in the flash-like manner to the heat insulating region B in synchronization with the flash supply of the process gas. As a result, it is possible to reduce the pressure difference between the processing region A and the heat insulating region B. Therefore, it is possible to prevent (or suppress) the process gas supplied to the processing region A from flowing down into the heat insulating region B. As a result, it is possible to ensure the uniform processing of the substrate S. In addition, by suppressing a downward flow of the process gas into the heat insulating region B (that is, preventing the process gas from flowing reversely into the heat insulating region B), it is possible to obtain an effect of preventing an adhesion of the by-products to the heat insulating region B.

When the inert gas is supplied to the heat insulating region B through the gas supply hole 291 and the gas supply pipe 292 provided at the positions opposite the gas exhaust structure 213 to obtain an effect of preventing the process gas from flowing reversely and to obtain the effect of preventing the adhesion of the by-products, it is possible to obtain a smooth flow of the inert gas. As a result, it is very preferable for ensuring the effect of preventing the process gas from flowing reversely and the effect of preventing the adhesion of the by-products.

### Second Specific Example

The supply of the inert gas to the heat insulating region B may be performed under a gas supply control in a second specific example described below, instead of the flash supply described in the first specific example described above.

When the inert gas is supplied to the heat insulating region B by the inert gas supply system 270, as shown in FIG. 2C, the valve 274 and the valve 277 are opened. Thereby, the inert gas is supplied to the heat insulating region B in the process chamber 201 by the inert gas supply system 270.

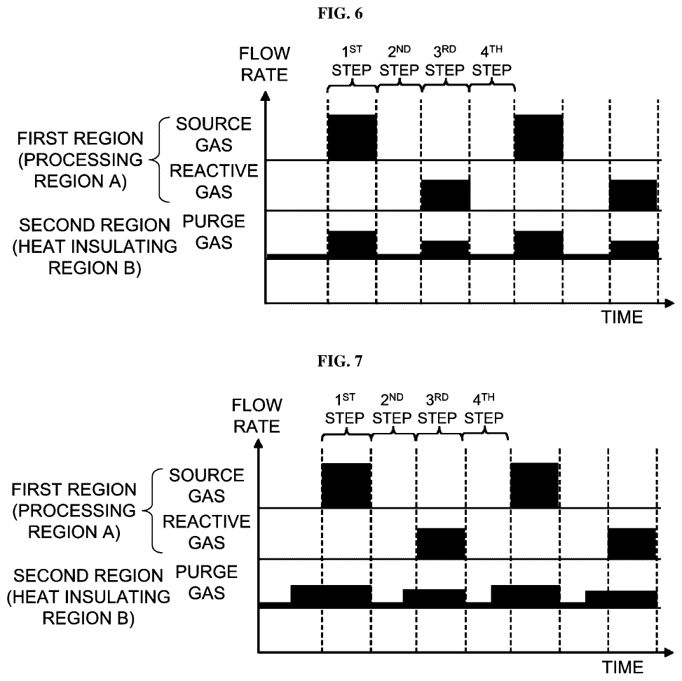

However, with respect to the timing of supplying the inert gas by the inert gas supply system 270, as shown in FIG. 7, the supply of the inert gas to the heat insulating region B is started before the flash supply of the first process gas (which is the source gas) to the processing region A in the first step is started, and the supply of the inert gas to the heat insulating region B is started before the flash supply of the second process gas (which is the reactive gas or the modification gas) to the processing region A in the third step is started. That is, the supply of the inert gas to the heat insulating region B is started before the flash supply of the first process gas in the first step is performed, and the supply of the inert gas to the heat insulating region B is started before the flash supply of the second process gas in the third step is performed.

The supply of the inert gas by the inert gas supply system 270 is started a predetermined time before the flash supply of the first process gas or the second process gas is started. In the present specific example, the term “predetermined time” refers to a sufficient time for the supply of the inert gas to the heat insulating region B to be ready until the supply of the inert gas to the heat insulating region B can be performed at a predetermined flow rate or a predetermined flow velocity.

The flow rate or the flow velocity of the inert gas may be substantially the same as in the first specific example.

When the gases are supplied to the processing region A and the heat insulating region B under such a gas supply control described above, even when the process gas is supplied in the flash-like manner to the processing region A, the inert gas has already been supplied to the heat insulating region B at a start of the flash supply of the process gas. As a result, it is possible to reduce the pressure difference between the processing region A and the heat insulating region B. As a result, similar to the first specific example, it is possible to obtain the effect of preventing the process gas from flowing reversely and the effect of preventing the adhesion of the by-products.

### Other Specific Examples

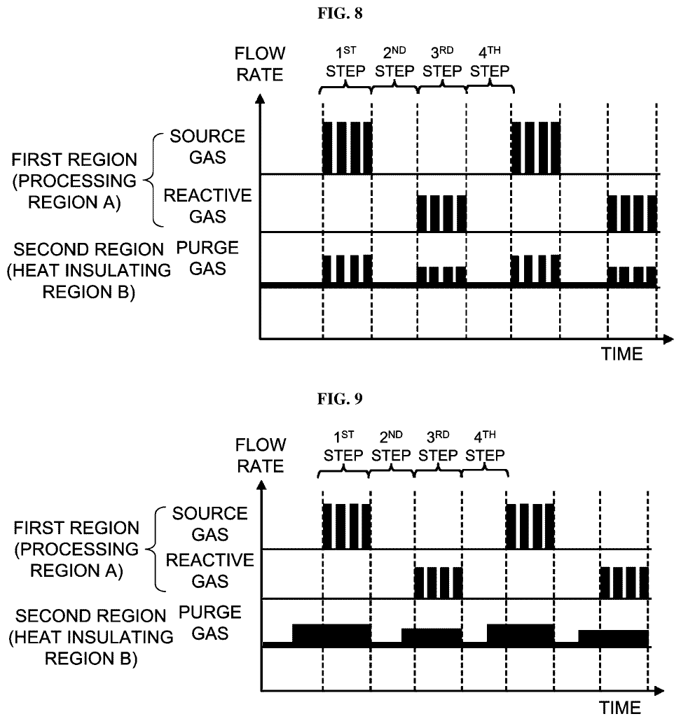

The flash supply of the first process gas (which is the source gas) to the processing region A in the first step and the flash supply of the second process gas (which is the reactive gas or the modification gas) to the processing region A in the third step may be performed intermittently a plurality of times in each of the first step and the third step, as shown in FIGS. 8 and 9.

In such a case, the supply of the inert gas to the heat insulating region B by the inert gas supply system 270 can be performed intermittently a plurality of times in each of the first step and the third step, in synchronization with each of the flash supply of the first process gas and the flash supply of the second process gas, as shown in FIG. 8, for example. When the gases are supplied to the processing region A and the heat insulating region B under such a gas supply control described above, similar to the first specific example, it is possible to reduce the pressure difference between the processing region A and the heat insulating region B. As a result, similar to the first specific example, it is possible to obtain the effect of preventing the process gas from flowing reversely and the effect of preventing the adhesion of the by-products.

In addition, for example, as shown in FIG. 9, the supply of the inert gas to the heat insulating region B by the inert gas supply system 270 can be performed such that the inert gas is supplied to the heat insulating region B before a first execution of the flash supply of the process gas in each of the first step and the third step. When the gases are supplied to the processing region A and the heat insulating region B under such a gas supply control described above, similar to the second specific example, it is possible to reduce the pressure difference between the processing region A and the heat insulating region B. As a result, similar to the second specific example, it is possible to obtain the effect of preventing the process gas from flowing reversely and the effect of preventing the adhesion of the by-products.

### (4) Effects According to Present Embodiments

According to the present embodiments, it is possible to obtain one or more of the following effects.

(a) According to the present embodiments, the first gas supplier configured to supply the process gas serving as the first gas and the inert gas supplier configured to supply the inert gas serving as the second gas are controlled such that the pressure difference between the processing region A serving as the first region and the heat insulating region B serving as the second region can be reduced by supplying the inert gas (which is the purge gas) when the process gas is supplied in the flash-like manner. Therefore, even when the process gas is supplied in the flash-like manner, it is possible to reduce the pressure difference between the processing region A and the heat insulating region B. As a result, it is possible to obtain the effect of preventing the process gas supplied to the processing region A from flowing reversely into the heat insulating region B and the effect of preventing the adhesion of the by-products to the heat insulating region B. Thus, it is remarkably preferable for ensuring the processing of the substrate S uniformly.

(b) According to the present embodiments, the inert gas is supplied to the heat insulating region B through the gas supply hole 291 and the gas supply pipe 292 provided at the positions opposite to the gas exhaust structure 213. Thereby, it is possible to obtain the smooth flow of the inert gas. As a result, it is remarkably preferable for ensuring the effect of preventing the process gas from flowing reversely and the effect of preventing the adhesion of the by-products.

### (5) Modified Examples

The technique of the present disclosure is described in detail by way of the embodiments mentioned above. However, the technique of the present disclosure is not limited thereto. The technique of the present disclosure may be modified in various ways without departing from the scope thereof.

For example, the embodiments mentioned above are described by way of an example in which, in the film forming process performed by the substrate processing apparatus 10, the film is formed on the substrate S by using the first process gas and the second process gas. However, the technique of the present disclosure is not limited thereto. That is, as the process gases used in the film forming process, other gases may be used to form different films. In addition, the technique of the present disclosure may also be applied to film forming processes using three or more different process gases as long as the three or more different process gases are non-simultaneously supplied (that is, supplied in a non-overlapping manner) to form various films. Specifically, as the first element, for example, an element such as titanium (Ti), silicon (Si), zirconium (Zr) and hafnium (Hf) may be used. In addition, for example, as the second element, for example, an element such as nitrogen (N) and oxygen (O) may be used. However, as mentioned above, it is preferable to use silicon (Si) as the first element.

For example, the embodiments mentioned above are described by way of an example in which the HCDS gas is used as an example of the first process gas. However, the technique of the present disclosure is not limited thereto. As the first process gas, for example, a gas containing silicon (Si) and further containing a Si—Si bond may be used. As the first process gas, for example, a gas such as tetrachloro dimethyl disilane ((CH₃)₂Si₂Cl₄, abbreviated as TCDMDS) and dichloro tetramethyl disilane ((CH₃)₄Si₂Cl₂, abbreviated as DCTMDS) may be used. The TCDMDS contains a Si—Si bond and further contains a chloro group and an alkylene group. In addition, the DCTMDS contains a Si—Si bond and further contains a chloro group and an alkylene group.

For example, the embodiments mentioned above are described by way of an example in which the film forming process is performed by the substrate processing apparatus 10. However, the technique of the present disclosure is not limited thereto. That is, the technique of the present disclosure may be applied not only to the film-forming process of forming the film exemplified in the embodiments mentioned above but also to other film-forming processes of forming other films. In addition, one or more constituents of the embodiments mentioned above may be substituted with one or more constituents of other embodiments, or may be added to other embodiments. Further, a part of one or more constituents of the embodiments mentioned above may be omitted, or substituted with or added by other constituents.

For example, the embodiments mentioned above are described by way of an example in which a batch type substrate processing apparatus capable of simultaneously processing a plurality of substrates is used to form a film. However, the technique of the present disclosure is not limited thereto. For example, the technique of the present disclosure may also be preferably applied when a single wafer type substrate processing apparatus capable of processing one or several substrates at a time is used to form the film. In addition, the embodiments mentioned above are described by way of an example in which a substrate processing apparatus including a hot wall type process furnace is used to form the film. However, the technique of the present disclosure is not limited thereto. For example, the technique of the present disclosure may also be preferably applied when a substrate processing apparatus including a cold wall type process furnace is used to form the film.

Process procedures and process conditions of each process using the substrate processing apparatuses exemplified above may be substantially the same as those of the embodiments or the modified examples mentioned above. Even in such a case, it is possible to obtain substantially the same effects as in the embodiments or the modified examples mentioned above.

According the modified examples mentioned above, it is possible to obtain substantially the same effects as in the embodiments mentioned above. In addition, the embodiments and the modified examples mentioned above may be appropriately combined. The process procedures and the process conditions of each combination thereof may be substantially the same as those of the embodiments mentioned above or the modified examples mentioned above.

As described above, according to some embodiments of the present disclosure, it is possible to provide a technique capable of processing the plurality of substrates uniformly.

What is claimed is:

1. A substrate processing apparatus comprising:
a process chamber in which a substrate is processed;
a first gas supplier configured to supply a first gas to a first region in the process chamber;
a second gas supplier configured to supply a second gas to a second region in the process chamber different from the first region; and
a controller configured to be capable of controlling the first gas supplier and the second gas supplier to supply the first gas and the second gas such that a pressure difference between the first region and the second region is reduced when the first gas is supplied in a flash-like manner.

2. The substrate processing apparatus of claim 1, wherein the first region comprises a substrate processing region in which the substrate is processed.

3. The substrate processing apparatus of claim 2, wherein the substrate processing region comprises a substrate accommodating region corresponding to a region in which the substrate and one or more substrates are supported by a substrate retainer.

4. The substrate processing apparatus of claim 1, wherein the second region comprises a heat insulating region for a heat insulator provided below a substrate retainer.

5. The substrate processing apparatus of claim 1, wherein the first gas supplier is provided with a flash tank, and is further configured to supply the first gas in the flash-like manner.

6. The substrate processing apparatus of claim 5, wherein the second gas supplier is provided with a flash tank, and is further configured to supply the second gas when the first gas is supplied in the flash-like manner.

7. The substrate processing apparatus of claim 1, wherein the second gas is supplied simultaneously with a supply of the first gas.

8. The substrate processing apparatus of claim 1, wherein the second gas is supplied before the first gas is supplied in the flash-like manner.

9. The substrate processing apparatus of claim 1, wherein the first gas and the second gas are different from each other.

10. The substrate processing apparatus of claim 9, wherein the first gas comprises a process gas and the second gas comprises a purge gas.

11. The substrate processing apparatus of claim 1, wherein the second gas supplier is provided at a lower portion of the process chamber.

12. The substrate processing apparatus of claim 11, wherein the second gas supplier is provided on a side surface of the process chamber below an upper end of the second region.

13. The substrate processing apparatus of claim 1, further comprising:
an exhauster configured to exhaust the first gas.

14. The substrate processing apparatus of claim 13, wherein the second gas supplier is provided at a position opposite to the exhauster.

15. A substrate processing method comprising:
(a) supplying a first gas to a first region in a process chamber; and
(b) supplying a second gas to a second region in the process chamber different from the first region,
wherein, in (b), the second gas is supplied such that a pressure difference between the first region and the second region is reduced when the first gas is supplied in a flash-like manner.

16. The substrate processing method of claim 15, wherein, in (b), the second gas is supplied simultaneously with the first gas being supplied in the flash-like manner.

17. The substrate processing method of claim 15, wherein, in (b), the second gas is supplied in a flash-like manner.

18. The substrate processing method of claim 15, wherein, in (b), the second gas is supplied before the first gas is supplied in the flash-like manner.

19. A method of manufacturing a semiconductor device, comprising:
the method of claim 15.

20. A non-transitory computer-readable recording medium storing a program that causes a substrate processing apparatus, by a computer, to perform:
(a) supplying a first gas to a first region in a process chamber; and
(b) supplying a second gas to a second region in the process chamber different from the first region,
wherein, in (b), the second gas is supplied such that a pressure difference between the first region and the second region is reduced when the first gas is supplied in a flash-like manner.
